(19) United States
(12) Patent Application Publication
(10) Pub. No.: US 2023/0119469 A1
(43) Pub. Date: Apr. 20, 2023

(54) MAGNETIC SHIELDING SHEET FOR RECEPTION ANTENNA, AND WIRELESS POWER RECEPTION MODULE INCLUDING SAME

(71) Applicant: AMOSENSE CO.,LTD., Cheonan-si, Chungcheongnam-do (KR)

(72) Inventor: Sung Hyun PARK, Cheonan-si, Chungcheongnam-do (KR)

(73) Assignee: AMOSENSE CO.,LTD., Cheonan-si, Chungcheongnam-do (KR)

(21) Appl. No.: 17/906,992

(22) PCT Filed: Mar. 24, 2021
(86) PCT No.: PCT/KR2021/003654

§ 371 Date: Sep. 22, 2022

(30) Foreign Application Priority Data
Mar. 24, 2020 (KR) 10-2020-0035758

(51) Int. Cl. H01F 27/36; H01Q 1/52

(52) U.S. Cl. CPC H01F 27/36; H01Q 1/526; H01Q 1/521

(57) ABSTRACT

A magnetic shielding sheet for a reception antenna, and a wireless power reception module including same are provided. A magnetic shielding sheet for a reception antenna, according to an exemplary embodiment of the present invention, blocks the magnetic field induced in a reception antenna, and comprises: a planar first shielding sheet including a through-hole penetratively formed with a predetermined area in a region corresponding to a hollow portion of the reception antenna; and a second shielding sheet arranged to come in contact with one surface of the first shielding sheet, so as to block the magnetic field leaking through the through-hole.

### CROSS REFERENCE TO RELATED APPLICATIONS

This application is a National Phase Entry of International Application No. PCT/KR2021/003654, filed on Mar. 24, 2021, designating the United States, which is based upon and claims priority to Korean Patent Application 10-2020-0035758, the entire contents of which are incorporated herein by reference.

### TECHNICAL FIELD

The disclosure relates to a magnetic field shielding sheet for a reception antenna and a wireless power reception module including the same.

### BACKGROUND

Wireless power transmission technology is very convenient because there is no need to use a separate cable in charging, and thus has been continuously tried to be applied to various electronic devices.

For example, wireless power transmission technology has been applied to a wearable device for detecting various pieces of user's biometric information, such as body temperature and heart rate while worn on a user's body.

In other words, the wearable device includes a built-in wireless power reception module to be paired with a wireless power transmission module, so its battery can be easily charged using wireless power received through the wireless power reception module.

In the wearable device, various electronic parts, such as a temperature sensor for measuring a user's body temperature and a heart rate sensor for acquiring a user's heart rate information, are installed in consideration of the overall size of the wearable device and the position of the wireless power reception module so as to not only smoothly acquire a wearer's biometric information but also smoothly receive wireless power through the wireless power reception module (the related art: Korean Patent No. 10-1617621).

For example, the foregoing electronic parts in the conventional wearable device are disposed at positions overlapping the wireless power reception module so as to not only smoothly acquire a wearer's biometric information but also smoothly receive wireless power.

Accordingly, a through hole having a predetermined area is formed on a magnetic field shielding sheet included in the wireless power reception module at a position corresponding to the electronic parts so that the foregoing electronic parts can smoothly work.

Due to this, the electronic parts can be operated smoothly through the through hole, but since a part of the magnetic field induced from the wireless power transmission module is inevitably leaked through the through hole of the magnetic field shielding sheet. Thus, there is a limit in that the wireless power transmission efficiency using the wireless power reception module is lowered.

### SUMMARY OF THE INVENTION

The disclosure has been conceived considering the foregoing points, and an aspect of the disclosure is to provide a magnetic field shielding sheet for a reception antenna and a wireless power reception module including the same, in which, even if the magnetic field shielding sheet includes a through hole formed through a predetermined area in consideration of a layout relationship with other electronic parts, the amount of magnetic field leaking through the through hole is minimized

According to one embodiment of the disclosure, there is provided a magnetic field shielding sheet for a reception antenna, which shields a magnetic field induced to a reception antenna, the magnetic field shielding sheet including: a first shielding sheet shaped like a plate and including a through hole formed through a predetermined area in a region corresponding to a hollow portion of the reception antenna; and a second shielding sheet disposed to be in contact with one surface of the first shielding sheet and shieling a magnetic field leaking through the through hole.

Further, the second shielding sheet may be disposed on one surface of the first shielding sheet to surround an edge of the through hole.

Further, the second shielding sheet may be disposed on one surface of the first shielding sheet to be positioned on the same surface as the reception antenna among both surfaces of the first shielding sheet.

Further, the reception antenna may be disposed on one surface of the first shielding sheet so that the second shielding sheet is positioned in the hollow portion.

Further, the reception antenna may be disposed on one surface of the first shielding sheet so that a pattern portion does not overlap the second shielding sheet.

Further, the first shielding sheet and the second shielding sheet may be made of the same material as each other.

For example, each of the first shielding sheet and the second shielding sheet may be any one of an amorphous ribbon sheet, a ferrite sheet, and a polymer sheet.

Further, the through hole may be a placement hole in which electronic parts are placed.

Meanwhile, according to one embodiment of the disclosure, there is provided a wireless power reception module including: a wireless power reception antenna including a hollow portion having a predetermined area, and a pattern portion formed to surround the hollow portion; and a magnetic field shielding sheet disposed on one surface of the wireless power reception antenna, and shielding a magnetic field induced to the wireless power reception antenna, wherein the magnetic field shielding sheet includes: a first shielding sheet shaped like a plate and including a through hole formed through a predetermined area in a region corresponding to the hollow portion; and a second shielding sheet disposed to be in contact with one surface of the first shielding sheet and shieling a magnetic field leaking through the through hole.

Further, the second shielding sheet may be disposed on one surface of the first shielding sheet so as to surround an edge of the through hole on the same surface on which the wireless power reception antenna is disposed among both surfaces of the first shielding sheet.

Further, the second shielding sheet may be disposed on one surface of the first shielding sheet so as not to overlap the pattern portion while being positioned in the hollow portion.

Further, the wireless power reception antenna may be a flat coil formed by winding a conductive member a plurality of times clockwise or counterclockwise, or an antenna pattern formed in a loop shape on at least one surface of a circuit board.

According to the disclosure, even if a magnetic field shielding sheet includes a through hole in consideration of a layout relationship with other electronic parts, the amount of magnetic field leaking through the through hole is minimized, thereby increasing the amount of magnetic field concentrated in the magnetic field shielding sheet and improving the performance of an antenna.

### BRIEF DESCRIPTION OF THE DRAWINGS

FIG. 1 is a view showing a magnetic field shielding sheet for a reception antenna according to one embodiment of the disclosure,

FIG. 2 is an exploded view of FIG. 1,

FIG. 3 is a view showing a wireless power reception module according to one embodiment of the disclosure,

FIG. 4 is an exploded view of FIG. 3, and,

FIG. 5 is a view conceptually showing a magnetic field shielding effect using a second shielding sheet in interaction between a wireless power reception module according to one embodiment of the disclosure and a wireless power transmission module.

### DETAILED DESCRIPTION

Embodiments of the disclosure will be described below in detail with reference to the accompanying drawings such that a person having ordinary knowledge in the art to which the disclosure pertains can easily implement the embodiments. The disclosure may be embodied in various forms, but not limited to the embodiments set forth herein. In the drawings, unrelated parts are omitted for the clarity of description, and like numerals refer like elements throughout.

A magnetic field shielding sheet 100 for a reception antenna according to one embodiment of the disclosure may be disposed on one surface of a reception antenna 10 that performs a predetermined function using a magnetic field at a predetermined frequency band.

Because of this, the magnetic field shielding sheet 100 for the reception antenna according to one embodiment of the disclosure shields a magnetic field induced to the reception antenna 10, thereby improving the performance of the reception antenna 10.

For example, the reception antenna 10 may be a wireless power reception antenna for receiving wireless power, a near field communication (NFC) antenna for transmitting or receiving a wireless data signal, and a magnetic secure transmission (MST) antenna for magnetic payment. In addition, the reception antenna may be configured in a combo type including two or more among the wireless power reception antenna, the NFC antenna and the MST antenna.

The magnetic field shielding sheet 100 may be made of a material having magnetism to shield a magnetic field.

For example, a Mn—Zn ferrite sheet, a Ni—Zn ferrite sheet, a ribbon sheet including at least one of an amorphous alloy and a nanocrystalline alloy, a polymer sheet, Permalloy, etc. may be used as the magnetic field shielding sheet 100.

Further, the magnetic field shielding sheet 100 may be a multi-layered sheet in which a plurality of sheets is stacked as multilayers with adhesive layers therebetween, and may be divided into a plurality of pieces to increase overall resistance for preventing occurrence of eddy current or improve flexibility.

Here, the material of the magnetic field shielding sheet 100 is not limited to the foregoing materials, but may include any known materials used as a shielding sheet for shielding the magnetic field.

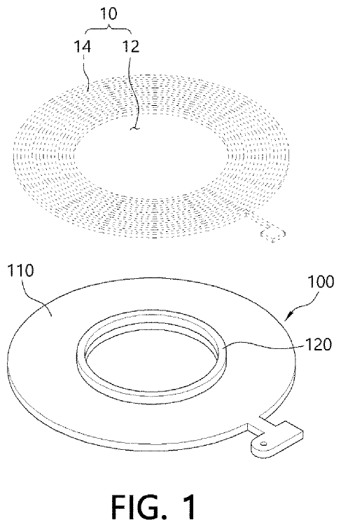

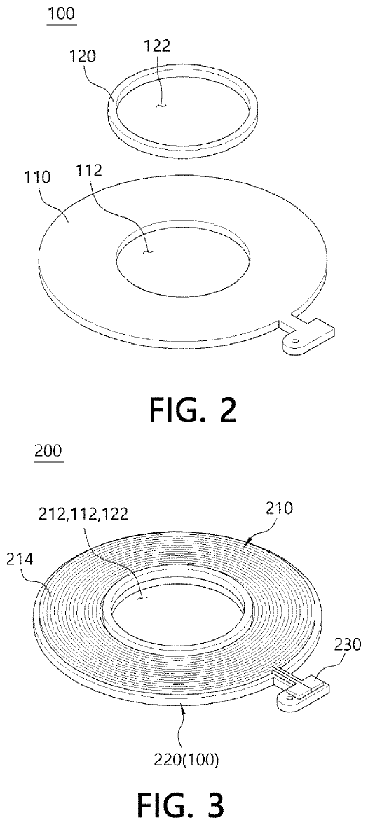

As shown in FIGS. 1 and 2, the magnetic field shielding sheet 100 for the reception antenna according to one embodiment of the disclosure may include a first shielding sheet 110, a second shielding sheet 120, and may include a through hole 112 that is formed through to have a predetermined area.

For example, the through hole 112 may be formed to pass through the first shielding sheet 110, and an opening 122 may also be formed through the second the shielding sheet 120 in a region corresponding to the through hole 112.

Here, in a wearable device including various electronic parts such as a temperature sensor, a heart rate sensor, etc., the through hole 112 and the opening 122 may be formed to be positioned at a position corresponding to the electronic parts. In addition, the through hole 112 and the opening 122 may be used as placement holes where the electronic parts are placed.

In this case, in the magnetic field shielding sheet 100 for the reception antenna according to one embodiment of the disclosure, the first shielding sheet 110 may function as a main shielding material by which a main magnetic field induced to the reception antenna 10 is shielded, and the second shielding sheet 120 may function as an auxiliary shielding material by which a part of a leaking magnetic field leaking through the opening 122 and the through hole 112 of the main magnetic field induced to the reception antenna 10 is reflected and induced towards the reception antenna 10.

Accordingly, the magnetic field shielding sheet 100 for the reception antenna according to one embodiment of the disclosure may improve the performance of the reception antenna 10 by inducing a part of the magnetic field, which leaks outwards through the through hole 112, towards the reception antenna 10 even if the through hole 112 formed through to have a predetermined area is included in consideration of a layout relationship with other electronic parts.

To this end, the first shielding sheet 110 may be shaped like a plate having a predetermined area to fully cover one surface of the reception antenna 10, and the second shielding sheet 120 may be disposed on one surface of the first shielding sheet 110 to surround the edge of the through hole 112.

In other words, the second shielding sheet 120 may be shaped forming a closed loop with the opening 122 at a central portion thereof to surround the edge of the through hole 112.

Here, the first shielding sheet 110 and the second shielding sheet 120 may be made of the same material or different materials, and the aforementioned materials may be used for the first shielding sheet 110 and the second shielding sheet 120.

In addition, the second shielding sheet 120 may be attached to and in contact with one surface of the first shielding sheet 110 by a separate adhesive layer, or may be formed integrally with the first shielding sheet 110.

In this case, the second shielding sheet 120 may be disposed on one surface of the first shielding sheet 110 to be positioned on the same surface as the reception antenna 10 among both surfaces of the first shielding sheet 110, and may be formed to have an area smaller than the whole area of the first shielding sheet 110.

Thus, a stepped surface may be formed between one surface of the first shielding sheet 110 and one surface of the second shielding sheet 120, and a pattern portion 14 of the reception antenna 10 may be disposed at a position corresponding to the remaining area except for an area on which the second shielding sheet 120 is disposed among the entire area of one surface of the first shielding sheet 110.

Accordingly, when the reception antenna 10 is disposed on one surface of the magnetic field shielding sheet 100 for the reception antenna according to one embodiment of the disclosure, the pattern portion 14 of the reception antenna 10 may be disposed on one surface of the first shielding sheet 110 so as not to overlap the second shielding sheet 120.

In other words, the reception antenna 10 may include a hollow portion 12 having a predetermined area at the center thereof, and the pattern portion 14 formed to surround the hollow portion 12. In addition, when the reception antenna 10 is disposed on one surface of the magnetic field shielding sheet 100 for the reception antenna according to one embodiment of the disclosure, the second shielding sheet 120 may be positioned in the hollow portion 12 and the pattern portion 14 of the reception antenna 10 may be disposed at a position corresponding to the remaining area except for an area on which the second shielding sheet 120 is disposed among the entire area of one surface of the first shielding sheet 110.

Accordingly, in the magnetic field shielding sheet 100 for the reception antenna according to one embodiment of the disclosure, the second shielding sheet 120 may be disposed to be positioned in the hollow portion 12 of the reception antenna 10 even if the second shielding sheet 120 for shielding the magnetic field leaking towards the through hole 112 protrudes from one surface of the first shielding sheet 110. As a result, the whole thickness of the magnetic field shielding sheet 100 can be maintained to have the same thickness as that of a conventional one, or an increase in the whole thickness of the magnetic field shielding sheet 100 due to the thickness of the second shielding sheet 120 can be minimized

Accordingly, in the magnetic field shielding sheet 100 for the reception antenna according to one embodiment of the disclosure, the increase in the thickness of the magnetic field shielding sheet 100 can be prevented or minimized while minimizing the amount of magnetic field leaking through the opening 122 and the through hole 112 to improve performance as the shieling sheet.

Meanwhile, the foregoing magnetic field shielding sheet 100 for the reception antenna may be applied to a wireless power reception module 200, and the wireless power reception module 200 may be built in a wearable device.

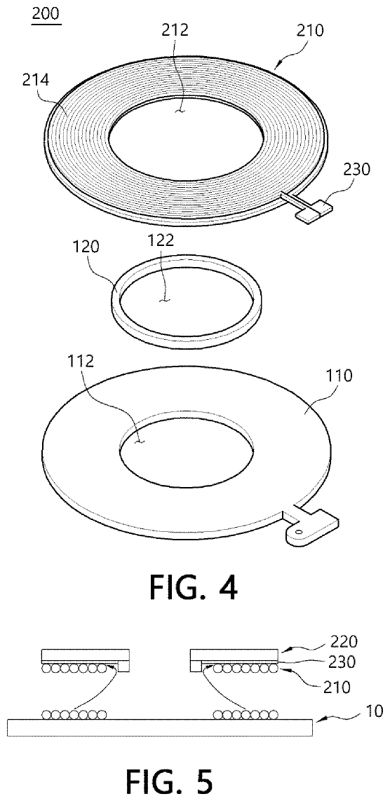

In other words, the wireless power reception module 200 according to one embodiment of the disclosure may include a wireless power reception antenna 210 and a magnetic field shielding sheet 220 as shown in FIGS. 3 and 4.

The wireless power reception antenna 210 may be disposed on one surface of the magnetic field shielding sheet 220, and receive wireless power transmitted from a wireless power transmission module 20.

In other words, the wireless power reception antenna 210 may receive a wireless power signal transmitted from the wireless power transmission module 20 using an inductive coupling method based on electromagnetic induction or magnetic resonance method.

Here, the wireless power transmission module 20 may, as shown in FIG. 5, include a wireless power transmission antenna 22 corresponding to the wireless power reception antenna 210, and a shielding sheet 24 disposed on one surface of the wireless power transmission antenna 22.

The wireless power reception antenna 210 may include a hollow portion 212 having a predetermined area at the center thereof, and a pattern portion 214 formed to surround the hollow portion 212.

For example, the wireless power reception antenna 210 may be provided as a flat coil formed by winding a conductive member a plurality of times clockwise or counterclockwise, or an antenna pattern formed in a loop shape on at least one surface of a circuit board 230 as shown in FIGS. 3 and 4.

The wireless power reception antenna 210 may be fixed to one surface of the magnetic field shielding sheet 220 with an adhesive layer therebetween.

The magnetic field shielding sheet 220 may be provided as a member shaped like a plate and having a predetermined area, and may be disposed on one surface of the wireless power reception antenna 210.

The magnetic field shielding sheet 220 may shield the magnetic field induced to the wireless power reception antenna 210 and increases the concentration of the magnetic field, thereby improving the performance of the wireless power reception antenna 210 that operates at a predetermined frequency band.

In other words, the magnetic field shielding sheet 220 may shield the magnetic field induced to the wireless power reception antenna 210 during wireless charging based on a magnetic induction method at a frequency band of 100 to 350 kHz or during wireless power transmission based on a magnetic resonance method at a frequency of 6.78 MHz, thereby improving the performance of the wireless power reception antenna 210.

Here, the magnetic field shielding sheet 220 comprising the wireless power reception module 200 may be the foregoing magnetic field shielding sheet 100 for the reception antenna.

In other words, the magnetic field shielding sheet 220 may include the first shielding sheet 110 and the second shielding sheet 120 as described above, and the second shielding sheet 120 may be disposed on one surface of the first shielding sheet 110 to surround the edge of the through hole 112 formed in the first shielding sheet 110.

Here, the through hole 112 may be formed to be located at a position corresponding to various electronic parts in the wearable device including the various electronic parts such as a temperature sensor and a heart rate sensor as described above, and may be used as a placement hole where the electronic parts are placed.

The magnetic field shielding sheet 220 including the first shielding sheet 110 and the second shielding sheet 120 is equivalent to the foregoing magnetic field shielding sheet 100 for the reception antenna, and thus detailed descriptions thereof will be omitted.

In this case, the wireless power reception antenna 210 may be disposed on one surface of the magnetic field shielding sheet 220 in order to minimize the amount of magnetic field leaking outwards through the through hole 112 of the magnetic field shielding sheet 220.

In other words, the wireless power reception antenna 210 may be disposed on one surface of the first shielding sheet 110 such that the second shielding sheet 120 is positioned in the hollow portion 212 while positioned on the same surface on which the second shielding sheet 120 is disposed among both surfaces of the first shielding sheet 110.

In this case, the second shielding sheet 120 may overlap the pattern portion 214 of the wireless power reception antenna 210 while being positioned in the hollow portion 212 of the wireless power reception antenna 210.

Accordingly, as shown in FIG. 5, when the wireless power reception module 200 according to one embodiment of the disclosure interacts with the wireless power transmission module 20, the second shielding sheet 120 may shield a part of the magnetic field transmitted from the wireless power transmission module 20 and leaking through the through hole 112.

In other words, in the wireless power reception module 200 according to one embodiment of the disclosure, a part of the magnetic field leaking through the through hole 112 may be shielded by the second shielding sheet 120 and induced towards the wireless power reception antenna 210.

As a result, the wireless power reception module 200 according to one embodiment of the disclosure may be improved in a charging efficiency using the wireless power reception antenna 210 as a larger amount of magnetic field is induced towards the wireless power reception antenna 210 even if the magnetic field shielding sheet 220 includes the through hole 112 having a predetermined area.

Moreover, in the wireless power reception module 200 according to one embodiment of the disclosure, the second shielding sheet 120 may be disposed to be positioned in the hollow portion 212 of the wireless power reception antenna 210 even if the second shielding sheet 120 for shielding the magnetic field leaking towards the through hole 112 protrudes from one surface of the first shielding sheet 110. As a result, the whole thickness of the magnetic field shielding sheet 220 can be maintained to have the same thickness as that of a conventional one, or an increase in the whole thickness of the magnetic field shielding sheet 220 due to the thickness of the second shielding sheet 120 can be minimized

Accordingly, in the wireless power reception module 200 according to one embodiment of the disclosure, the increase in the whole thickness of the magnetic field shielding sheet 220 can be prevented or minimized while minimizing the amount of magnetic field leaking through the through hole 112 to improve the wireless charging efficiency.

Although embodiments of the disclosure have been described, the spirit of the disclosure is not limited to the embodiments disclosed herein, and modification, change, deletion, addition of elements can be easily made by those skilled in the art without departing from the scope of the disclosure.

1. A magnetic field shielding sheet for a reception antenna, which shields a magnetic field induced to a reception antenna, the magnetic field shielding sheet comprising:
a first shielding sheet shaped like a plate and comprising a through hole formed through a predetermined area in a region corresponding to a hollow portion of the reception antenna; and
a second shielding sheet disposed to be in contact with one surface of the first shielding sheet and shieling a magnetic field leaking through the through hole.

2. The magnetic field shielding sheet of claim 1, wherein the second shielding sheet is disposed on one surface of the first shielding sheet to surround an edge of the through hole.

3. The magnetic field shielding sheet of claim 1, wherein the second shielding sheet is disposed on one surface of the first shielding sheet to be positioned on the same surface as the reception antenna among both surfaces of the first shielding sheet.

4. The magnetic field shielding sheet of claim 1, wherein the reception antenna is disposed on one surface of the first shielding sheet so that the second shielding sheet is positioned in the hollow portion.

5. The magnetic field shielding sheet of claim 1, wherein the reception antenna is disposed on one surface of the first shielding sheet so that a pattern portion does not overlap the second shielding sheet.

6. The magnetic field shielding sheet of claim 1, wherein the first shielding sheet and the second shielding sheet are made of the same material as each other.

7. The magnetic field shielding sheet of claim 1, wherein each of the first shielding sheet and the second shielding sheet is any one of an amorphous ribbon sheet, a ferrite sheet, and a polymer sheet.

8. The magnetic field shielding sheet of claim 1, wherein the through hole is a placement hole in which electronic parts are placed.

9. A wireless power reception module comprising:
a wireless power reception antenna comprising a hollow portion having a predetermined area, and a pattern portion formed to surround the hollow portion; and
a magnetic field shielding sheet disposed on one surface of the wireless power reception antenna, and shielding a magnetic field induced to the wireless power reception antenna,
the magnetic field shielding sheet comprising:
a first shielding sheet shaped like a plate and including a through hole formed through a predetermined area in a region corresponding to the hollow portion; and
a second shielding sheet disposed to be in contact with one surface of the first shielding sheet and shieling a magnetic field leaking through the through hole.

10. The wireless power reception module of claim 9, wherein the second shielding sheet is disposed on one surface of the first shielding sheet so as to surround an edge of the through hole on the same surface on which the wireless power reception antenna is disposed among both surfaces of the first shielding sheet.

11. The wireless power reception module of claim 9, wherein the second shielding sheet is disposed on one surface of the first shielding sheet so as not to overlap the pattern portion while being positioned in the hollow portion.

12. The wireless power reception module of claim 9, wherein the first shielding sheet and the second shielding sheet are made of the same material as each other.

13. The wireless power reception module of claim 9, wherein each of the first shielding sheet and the second shielding sheet is any one of an amorphous ribbon sheet, a ferrite sheet, and a polymer sheet.

14. The wireless power reception module of claim 9, wherein the through hole is a placement hole in which electronic parts are placed.

15. The wireless power reception module of claim 9, wherein the wireless power reception antenna is a flat coil formed by winding a conductive member a plurality of times clockwise or counterclockwise, or an antenna pattern formed in a loop shape on at least one surface of a circuit board.
